(19) United States
(12) Patent Application Publication
(10) Pub. No.: US 2007/0079041 A1
(43) Pub. Date: Apr. 5, 2007

(54) Multiprocessor system

(75) Inventors: Shan-Kai Yang, Taipei (TW); Shi-Jun Ni, Shanghai (CN); Jian Shen, Shanghai (CN); Lei Ding, Shanghai (CN); Hai-Ming Ding, Shanghai (CN)

Correspondence Address: BACON & THOMAS, PLLC, 625 SLATERS LANE, FOURTH FLOOR, ALEXANDRIA, VA, 22314, US

(73) Assignee: TYAN COMPUTER CORP., Taipei (TW)

(21) Appl. No.: 11/346,247

(22) Filed: Feb. 3, 2006

(30) Foreign Application Priority Data
Sep. 30, 2005 (TW) 094134284

(51) Int. Cl. H05K 7/10; G06F 13/00

(52) U.S. Cl. 710/301

(57) ABSTRACT

A multiprocessor system according to this invention comprises a main board, an expansion board, and at least a connection card. The main board comprises a plurality of first processors, such as four (4) CPUs, and at least a first socket. The expansion board comprises a plurality of second processors, such as four (4) CPUs, and at least a second socket. The plurality of first processors selectively communicates with each other by way of a plurality of first processor buses, which may be dual unidirectional point-to-point buses such as HT buses. The plurality of second processors selectively communicates with each other by way of a plurality of second processor buses, which may be dual unidirectional point-to-point buses such as HT bus. The connection card(s) electronically connect(s) to the first socket(s) and the second socket(s) for providing connection between at least one of the first processor of the main board and at least one of the second processor of the expansion board.

### CROSS-REFERENCE

This application is based upon and claims the benefit of priority from prior Taiwanese Patent Application No. 094134284, filed on Sep. 30, 2005. The prior application is herewith incorporated by reference in its entirety.

### BACKGROUND OF THE INVENTION

1. Field of the Invention

The present invention relates to a processor system, and more particularly, to a multiprocessor system.

2. Description of the Related Art

Because the data processing requirement is rising, the number of the processors is increasing. As the design of such multiprocessor systems evolves, and as the technology available for that design becomes more complex, limits on the construction of such systems are encountered. One such limit involves the configuration size of the multiprocessor system itself. Undoubtedly, a compact and slim multiprocessor system is more popular in the current miniaturization trend. However, the configuration of processor units on the multiprocessor should be separated as far as possible for better heat-dissipation. On the contrary, the processor units should be closer to each other if we want to get a faster transmission speed for data. Therefore, the size and the transmission speed are contradictory to the configuration for better heat-dissipation. Traditionally, referring to FIG. 1, the configuration of a multiprocessor system 1, such as an 8-way processing system, comprises a main board 10, a plurality of connectors 16, and a plurality of processor unit cards 12, such as four connectors 16 and four processor cards 12. Each processor unit card 12 may be inserted into each connector 16.

In the multiprocessor system 1, each processor unit card 12 has two processor units 14a and 14b, 14c and 14d, 14e and 14f, or 14g and 14h thereon.

When the processor unit cards 12 are inserted into the connectors 16 respectively, the communication between the processor units 14a, 14b, 14c, 14d, 14e, 14f, 14g, or 14h on different cards 12, such as between processor units 14a and 14c, must be made by way of the main board 10. As those skilled in this art should understand that some signal loss or signal integrity problems may occur between the connectors 16 and the processor unit cards 12 because of relevant long buses configured for card-board-card or card-board structure. In addition, in order to avoid heat-dissipation problem, two adjacent processor unit cards 12 should be spaced out with an enough distance, which may be configured with relevant long buses for connecting two adjacent processor unit cards 12. However, there exist some contradictories in the configuration of size and the space.

Please refer to FIG. 2. The communication, for example, between the processor units 14a and 14d must be made by way of card-board-card bus 20a and processor bus 21b or by way of bus processor bus 21a and card-board-card bus 20b. Furthermore, the communication between the processor units 14a and 14h must be made by way of buses 20a, 20c, 20e, and 21d. In general, the transmission speed for data in bus 20a-20e may be slower than bus 21a -21d because the later transmission is based on processor bus that is designed on the same card 12 instead of by way of the main board 10.

Since the processor units 14a-14h mounted on each processor unit card 12 must be connected by the buses 20a-20f and/or 21a-21d, the spacing between the processor units 14a-14h becomes critical as a result of the electrical characteristics of the buses 20a-20f and/or 21a-21d. Thus, for example, if the space between processor units 14a-14h becomes too large, the electrical characteristics of the buses 20a-20f and/or 21a-21d can place severe limitation on bus speed, the number of processor units 14a-14h that may be connected, and the like. Nowadays, the bus communication can use HyperTransport™ (HT) technology, which is a dual unidirectional point-to-point high-bandwidth and low-latency computer bus. The HT Specification is clearly defined and maintained by the HT Consortium for promoting and developing HT technology. HT technology's aggregate bandwidth of 22.4 GB/sec represents better than a 70-fold increase in data throughput over PCI buses. While providing far greater bandwidth, HT technology complements legacy I/O standards like PCI as well as emerging technologies like PCI-X and PCI-Express. HT technology may provide a flexible, scalable interconnect architecture designed to reduce the number of buses within the system.

As a result, in order to have a better performance for a multiprocessor system, it is desired to have a multiprocessor system with shorter space between processor units and using dual unidirectional point-to-point buses for better transmission speed and compatibility, which has not been shown in the prior art.

### SUMMARY OF THE INVENTION

A main objective of the present invention is to provide a multiprocessor system that may overcome the problem of heat-dissipation and/or signal loss. The multiprocessor system according to this invention comprises a main board, an expansion board located above or under the main board, and at least a connection card. The main board, such as a server motherboard, comprises a plurality of first processors, such as four CPUs, and at least a first socket. The expansion board comprises a plurality of second processors, such as four CPUs, and at least a second socket. Therefore, the expansion board may expand the number of the processors for the main board, for example up to eight processors.

The plurality of first processors selectively communicates with each other by way of a plurality of first processor buses, preferably by way of dual unidirectional point-to-point buses, such as HT bus. Similarly, the plurality of second processors selectively communicates with each other by way of a plurality of second processor bus, such as HT bus.

The number of the connection card(s) and the shape of the connection card(s) can be variable depending on the number of processors and/or the requirement of data processing. In a preferred embodiment, there are two connection cards used to provide electronically connection between at least one of the first processor of the main board and at least one of the second processor of the expansion board. Preferably, each first socket and each second socket respectively comprises a slot for each connection card to be inserted into. The connection cards are inserted into the first sockets and the second sockets for providing connection between the main board and the expansion board.

Furthermore, the number of the first socket(s) and the second socket(s) are respectively corresponding to the number of the connection card(s) or the shape of the connection card for inserting into. For example, one connection card is used to insert into one first socket of the main board and one second socket of the expansion board. Alternatively, one connection card can be configured for being inserted into two first sockets and two second sockets. It should be understood that the number of the connection card(s), the first socket(s), or the second socket(s) is not used to limit the present invention.

Particularly, the first socket, the second socket, and the connection card are respectively compatible as a dual unidirectional point-to-point interface, such as a HT interface, for high-performance communication.

Each slot of the first socket and each slot of the second socket respectively comprise a plurality of pins. The pins of the slot in each first socket and in each second socket are defined as HT pins. And, each connection card comprises a plurality of first contact pads and a plurality of second contact pads corresponding to the pins of the slot of the first socket and the second socket respectively for electronically connection. Thus, when the connection card is inserted into the first socket and the second socket, the first contact pads are contacting to the pins of the first socket of the main board, and the second contact pads are contacting to the pins of the second socket of the expansion board. Each connection card further comprises a plurality of connection lines forming a third connection card bus for providing connection between the first contact pads and the second contact pads thereof. Conformably, the first contact pads and the second contact pads are defined as HT contact pads. And the third connection card bus is compatible as a HT bus.

Preferably, the physical structure of each first socket and each second socket, according to this invention, are respectively compatible as a PCI-Express socket, which can take advantage of saving the manufacture cost. Each first socket or each second socket may further respectively comprise a covering thereon, and the covering comprises a Y-shaped opening for guiding each connection card inserted into the first socket or the second socket.

In a preferred embodiment, the multiprocessor system according to this invention further comprises a supporting means to support at least the connection card. Furthermore, the supporting means may comprise at least a sustaining portion corresponding to the connection card(s) respectively for fixing the connection card(s) thereon. The supporting means further comprises at least a fixing member for fixing with a case of the multiprocessor system.

The main board further comprises an outward-connection bus for receiving or transmitting for at least one of the first processor to communicate with a chipset, such as a south bridge or a north bridge.

### BRIEF DESCRIPTION OF THE DRAWINGS

FIG. 1 is a schematic view illustrating the conventional 8-way processing system according to the prior art.

FIG. 2 is a block diagram according to FIG. 1.

FIG. 3A-FIG. 3C are schematic views according to variety of embodiments with different connection card(s) and socket(s) of a multiprocessor system of the present invention.

FIG. 4 is another schematic view of a multiprocessor system with a different first socket and second socket according to the present invention.

FIG. 5 shows cross-section perspective enlarged view of a socket according to FIG. 4.

FIG. 6 shows a different perspective view of a multiprocessor system with a supporting means.

FIG. 7 is a block diagram of the multiprocessor system according to FIG. 6.

### DETAILED DESCRIPTION OF THE PREFERRED EMBODIMENT

Other objects, advantages, and novel features of the invention will become more apparent from the following detailed description when taken in conjunction with the accompanying drawings.

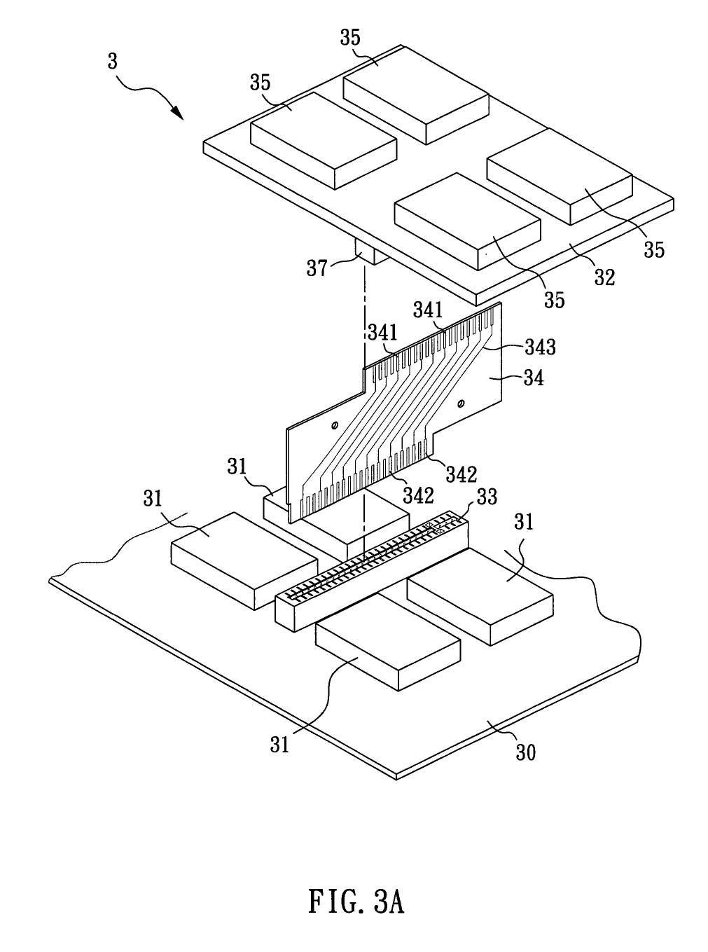

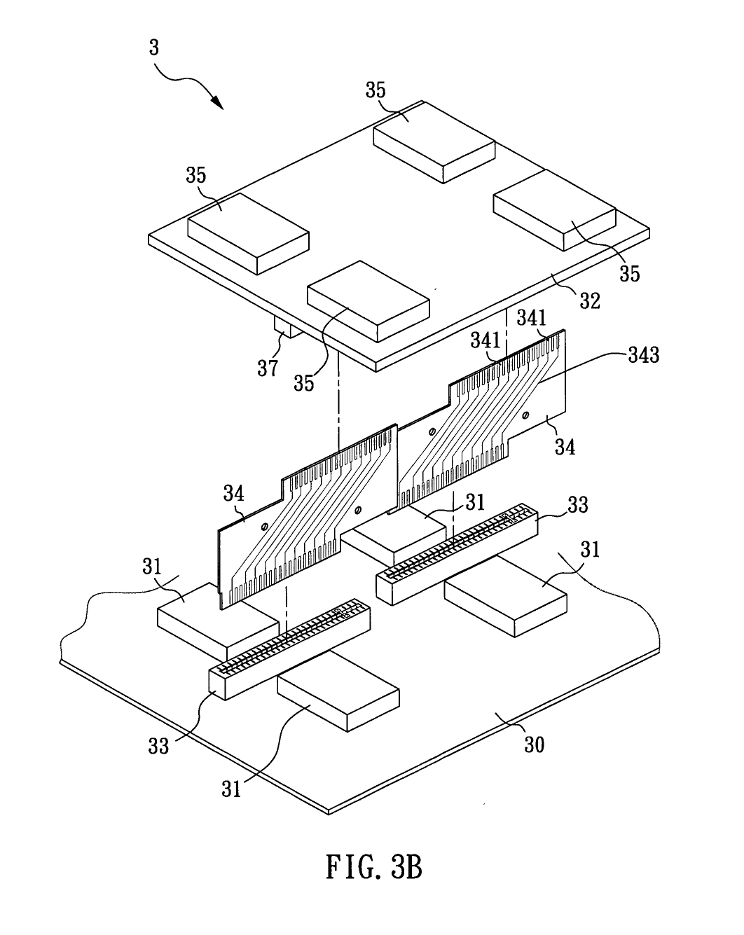

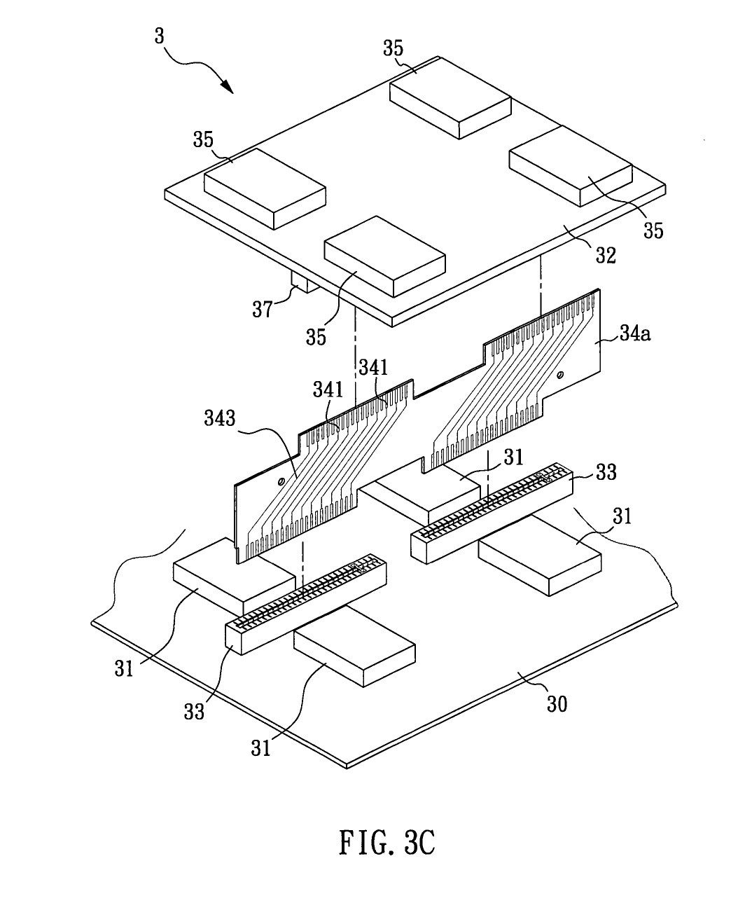

Please refer to FIG. 3A. A multiprocessor system 3 according to the present invention comprises a main board 30, an expansion board 32, and a connection card 34, wherein the expansion board 32 may be located above or under the main board 30 but not configured side by side. The main board 30 comprises a plurality of first processors 31, such as four CPUs, and a first socket 33. The expansion board 32 comprises a plurality of second processors 35, such as four CPUs, and a second socket 37. The connection card 34 can be inserted into the first socket 33 and the second socket 37 for providing connection between at least one of the first processor 31 and at least one of the second processor 35. According to the present invention, the main board 30 and the expansion board 32 is able to form the multi-processor system 3, such an 8-way multi-processor system, by the connection card 34.

It should be understood by those persons skilled in this art that the shape of the connection card 34 or the number of the connection card 34 is not used to limit the present invention, which may be variable depending on the requirement of data processing and/or the number of processors 31 or 35. Please see FIG. 3B, it shows two connection cards 34 to be inserted into two first sockets 33 of the main board 30 and into two second sockets 37 (not shown completely in FIG. 3B) of the expansion board 32 to provide electronically connection between at least one of the first processor 31 and at least one of the second processor 35.

Alternatively, two connection cards 34 can be formed as one connection card 34a, please see FIG. 3C, and the shape of the connection card 34a can make it being inserted into two first sockets 33 of the main board 30 and into two second sockets 37 (not shown completely in FIG. 3C) of the expansion board 32. It should be understood that neither the shape of the connection card 34a nor the number of the connection cards 34 is used to limit the present invention. And, neither the number of the first socket(s) 33 nor of the second socket(s) 37 is used to limit the present invention.

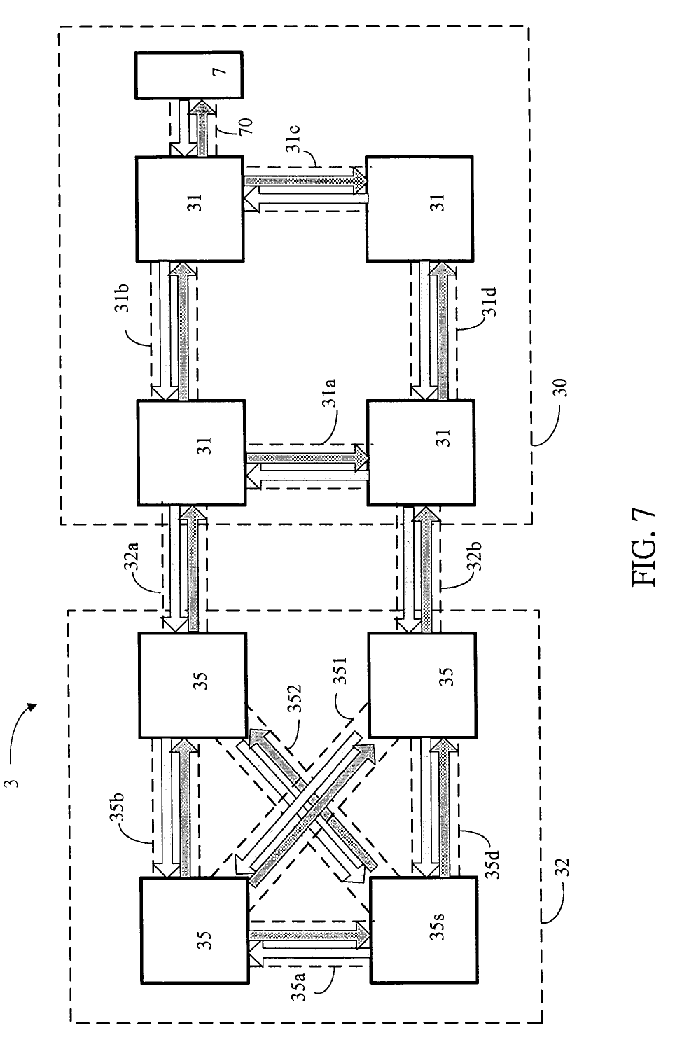

Accordingly, the connection card 34 (or 34a) provided by this invention comprises a plurality of first contact pads 341, a plurality of second contact pads 342, and a plurality of connection lines 343. The connection lines 343 may be provided for electronically connection between the first contact pads 341 and the second contact pads 342. Preferably, the first contact pads 341 and the second contact pads 342 are defined respectively for dual unidirectional point-to-point communication, such as HyperTransport™ (HT) pads. And, the connection lines 343 are correspondingly compatible for dual unidirectional point-to-point communication, such as HyperTransport (HT) communication. Furthermore, the connection lines 343 may form a connection card bus (as shown in FIG. 7 with reference number 32a or 32b) for providing connection between the first contact pads 341 and the second contact pads 342. Accordingly, the connection card bus is compatible as dual unidirectional point-to-point bus, such as HyperTransport (HT) bus.

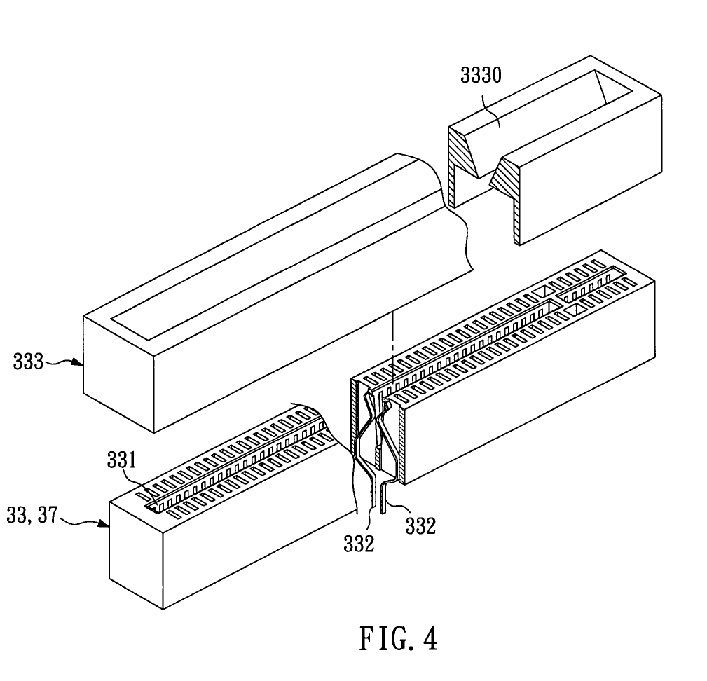

The first socket 33 and the second socket 37 may be same. The first socket 33 and the second socket 37 according to this invention may be respectively defined as a HT socket. Furthermore, referring to FIG. 4, each first socket 33 or each second socket 37 comprises a slot 331 for the connection card 34 or 34a (shown in FIG. 3A-FIG. 3C) to be inserted into. The slot 331 further comprises a plurality of pins 332. Each pin 332 is configured as a zigzag shape, and every two pins 332 are configured in opposite, so that the connection card 34 or 34a can be pressed by the pins 332 from both side thereof. Conformably, the pins 332 are correspondingly compatible for dual unidirectional point-to-point communication, for example defined as HT pins. The pins 332 are corresponding to the first contact pads 341 and/or the second contact pads 342 for electronically contact therebetween.

Particularly, the physical structure of the first socket 33 and the second socket 37, according to this invention, are respectively compatible as a PCI-Express socket.

When the connection card 34 or 34a is inserted into the slot 331 and pressed by the pins 332, the first contact pads 341 and the second contact pads 342 of the connection card 34 or 34a electronically contact with the pins 331 of the first socket 33 and the second socket 37 respectively. Accordingly, the connection card 34 or 34a may provide electronically connection between the main board 30 and the expansion board 32 for connecting at least one of the first processor 31 to at least one of the second processor 35.

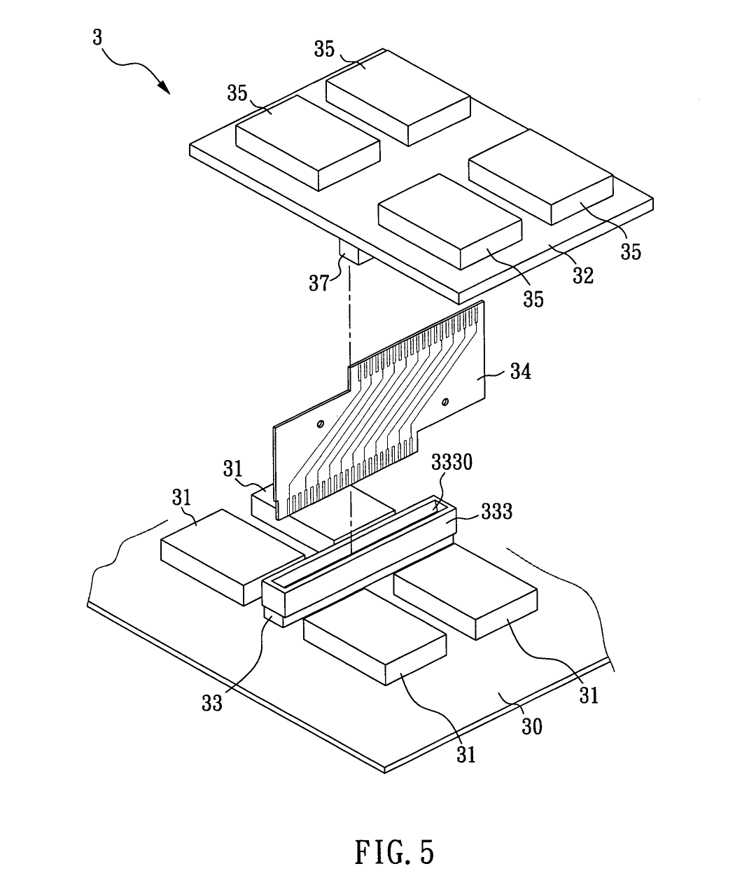

In order to guide the connection card 34 or 34a being inserted into the slot 331 of the first socket 33 or the second socket 37, in a preferred embodiment, the first socket 33 or the second socket 37 according to the present invention further comprises a covering 333 to be partially covered on the first socket 33 or the second socket 37. The covering 333 comprises a Y-shaped opening 3330 for guiding each connection card 34 or 34a to be inserted into the first socket 33 or the second socket 37. Please see the FIG. 5, comparing with the first socket 33 shown in FIG. 3A, the covering 333 can provide a bigger opening, the Y-shaped opening 3330, for the connection card 34 to be inserted into more easily.

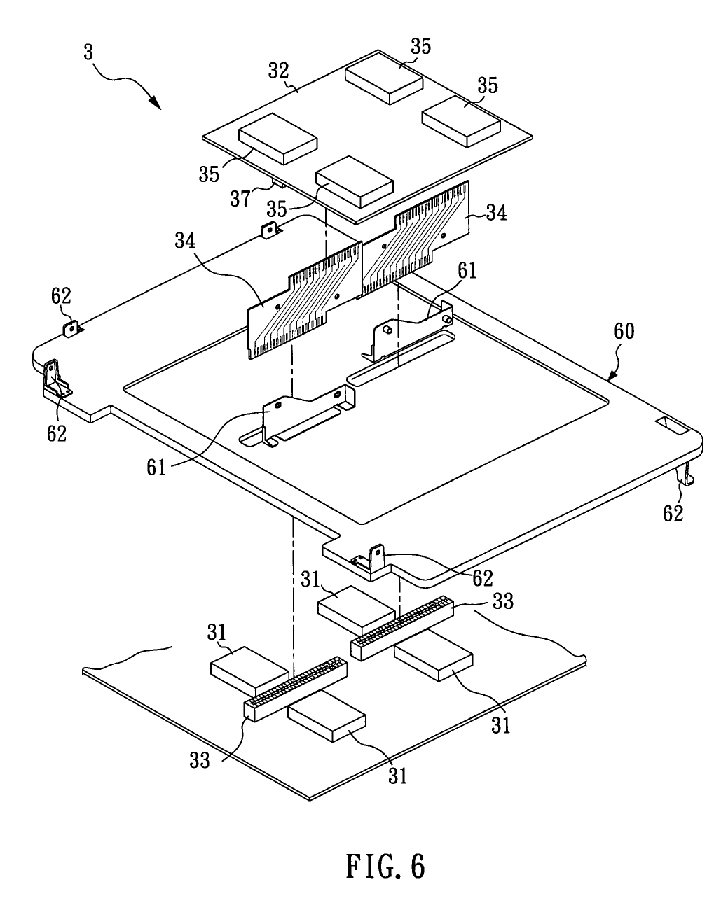

In another preferred embodiment, referring to FIG. 6, the multiprocessor system 3 according to this invention may further comprise a supporting means 60 to support at least one of the connection cards 34, for example two connection cards 34. Furthermore, the supporting means 60 may comprise at least a sustaining portions 61 corresponding to the connection card(s) 34 respectively to fix the connection card(s) 34 thereon. In another word, when there is only one connection card 34 provided for connection between the main board 30 and the expansion board 32, the number of the sustaining portion 61 is only one, though in FIG. 6, it shows two sustaining portions 61 for supporting two connection cards 34. It should be understood that the number of the sustaining portion 61 is not used to limit the present invention.

Normally, the multiprocessor system 3 may be covered by a case (not shown). Accordingly, the supporting means 60 may further comprise at least a fixing member 62 for fixing with the case of the multiprocessor system 3.

Please refer to FIG. 7. The first processors 31 selectively communicate with each other by way of a plurality of first processor buses 31a-31d, which can be dual unidirectional point-to-point buses, such as HyperTransport (HT) buses. Similarly, the second processors 35 selectively communicate with each other by way of a plurality of second processor bus 35a-35d, 351, and 352, which can be dual unidirectional point-to-point bus, such as HyperTransport (HT) bus. It should be understood that the processor buses 31a-31d, 35a-35d, 351, and 352 could be configured according to a circuit designed in a multi-layer printed circuit board (PCB), and the multi-layer printed circuit board can be a basis of the main board 30 or the expansion board 32. Thus, the processor buses 31a-31d, 35a-35d, 351, or 352 are used for illustration instead of limitation for the present invention.

According to the present invention, the main board 30 may further comprise an outward-connection bus 70 for receiving or transmitting for at least one of the first processor 31 to communicate with a chipset 7, such as a south bridge or a north bridge. For example, if data in the second processor 35s needs to be transmitted to the chipset 7, it will be transmitted by way of processor bus 352, connection card bus 32a, processor bus 31b, and outward-bus 70. The connection bus 32b or 32a, is provided by the connection card 34, as described above.

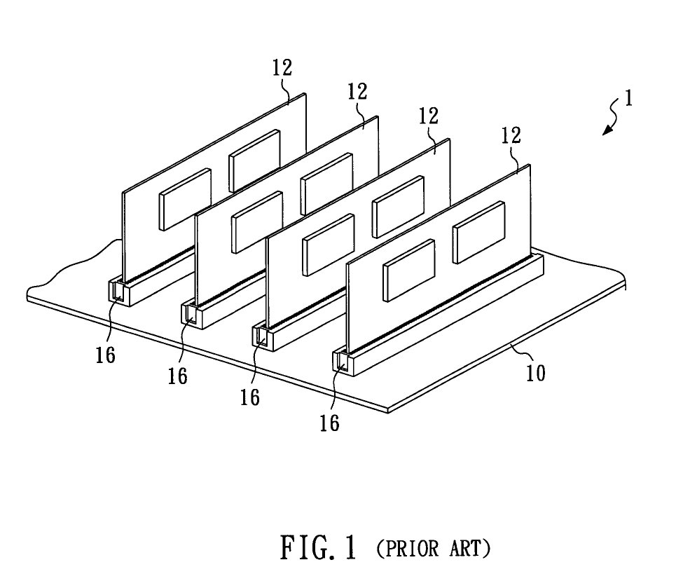

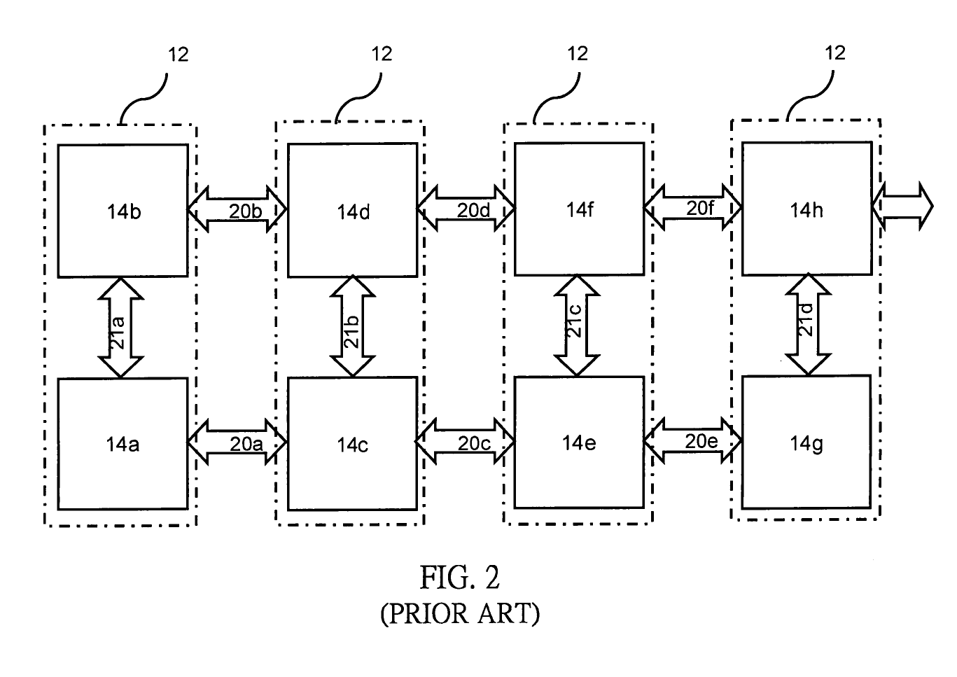

The present invention uses an easer way to build processor buses, such as layout in the PCB. In addition, for example, the processor units 31 or 35, such as AMD Operon™ processor unit, may be connected with three HT buses. The processor buses 35a, 35d, 31b, and 31d and the crossed processor buses 351, and 352 may provide less latency than those by way of connectors 16 in FIG. 1 of the prior art. In addition, according to the present invention, it may save cost from having fewer sockets 33 or 37 comparing with the connectors 16 (shown in FIG. 1) of the prior art.

Although the present invention has been explained in relation to its preferred embodiment, it is to be understood that many other possible modifications and variations can be made without departing from the spirit and scope of the invention as hereinafter claimed.

What is claimed is:

1. A multiprocessor system, comprising:
a main board comprising a plurality of first processors and at least a first socket, and wherein the plurality of first processors selectively communicate with each other by way of a plurality of first processor buses;
an expansion board located above or under the main board, the expansion board comprising a plurality of second processors and at least a second socket, and wherein the plurality of second processors selectively communicate with each other by way of a plurality of second processor buses; and
at least a connection card electronically connecting at least one of the first socket and at least one of the second socket for providing connection between at least one of the first processor of the main board and at least one of the second processor of the expansion board.

2. The multiprocessor system as claimed in claim 1, wherein the first processor buses and the second processor buses are dual unidirectional point-to-point buses.

3. The multiprocessor system as claimed in claim 2, wherein at least the first socket, the second socket, and the connection card are respectively compatible as a HyperTransport (HT) interface.

4. The multiprocessor system as claimed in claim 1, wherein at least the first socket and at least the second socket respectively comprise a slot for each connection card to be inserted into.

5. The multiprocessor system as claimed in claim 4, wherein each slot of the first socket and the second socket comprises a plurality of pins, and each connection card comprises a plurality of first contact pad and a plurality of second contact pad corresponding to the pins of the slot of each first socket and each second socket respectively for electronically connecting therebetween.

6. The multiprocessor system as claimed in claim 5, wherein each pin is configured as a zigzag shape, and every two pins are configured in opposite such that the connection card can be pressed from both side thereof.

7. The multiprocessor system as claimed in claim 5, wherein each connection card further comprises a plurality of connection lines forming a third connection card bus for providing connection between the first contact pads and the second contact pads.

8. The multiprocessor system as claimed in claim 1, wherein the physical structure of each first socket and each the second socket are respectively compatible as a PCI-Express socket.

9. The multiprocessor system as claimed in claim 5, wherein the first contact pads or the second contact pads are defined as HyperTransport (HT) pads.

10. The multiprocessor system as claimed in claim 5, wherein the pins of the slot of at least the first socket or the second socket are defined as HyperTransport (HT) pins.

11. The multiprocessor system as claimed in claim 1, wherein at least the first socket or the second socket further respectively comprises a covering thereon, the covering comprising a Y-shaped opening for guiding one of the connection card inserted into the first socket or the second socket.

12. The multiprocessor system as claimed in claim 1, further comprising a supporting means for supporting at least the connection card.

13. The multiprocessor system as claimed in claim 12, wherein the supporting means further comprises at least a sustaining portion corresponding to at least the connection card respectively for fixing the connection card respectively.

14. The multiprocessor system as claimed in claim 12, wherein the supporting means further comprises at least a fixing member for fixing with a case of the multiprocessor system.

15. The multiprocessor system as claimed in claim 1, wherein the main board further comprises an outward-connection bus for receiving or transmitting for at least one of the first processor.

16. The multiprocessor system as claimed in claim 1, wherein the number of the first processors is four, and the number of the second processors is four.

17. A connection card for connecting a main board and an expansion board, wherein the main board is located above or under the expansion board, the connection card comprising:
at least a first contact pad for electronically connecting to a first socket of the main board;
at least a second contact pad for electronically connecting to a second socket of the expansion board; and
at least a processor bus for connecting at least the first contact pad and at least the second contact pad.

18. The connection card as claimed in claim 17, wherein the first socket and the second socket respectively comprise a slot for the connection card to be inserted into.

19. The connection card as claimed in claim 18, wherein each of the slot of the first socket and the slot of the second socket comprises a plurality of pins for providing connection with the first contact pads and the second contact pads respectively.

20. The connection card as claimed in claim 17, wherein the first contact pads and the second contact pads are respectively defined as HyperTransport (HT) pads.

21. The connection card as claimed in claim 17, wherein each of the processor bus is a dual unidirectional point-to-point bus.

22. The connection card as claimed in claim 21, wherein each of the processor bus is compatible as a HyperTransport (HT) bus.

23. The connection card as claimed in claim 17, wherein the physical structure of first socket and the second socket are respectively compatible as a PCI-Express socket.

24. The connection card as claimed in claim 17, wherein the main board and the expansion board respectively comprise a plurality of processors for data processing.

25. A main board, comprising:
a plurality of processors configured thereon; and
a dual unidirectional point-to-point bus socket for providing connection between a connection card and the processors;
wherein the physical structure of the dual unidirectional point-to-point bus socket is compatible as a PCI-Express socket, and the dual unidirectional point-to-point bus socket comprises a slot used for the connection card to be inserted into and a plurality of pins used for electronically connecting to the connection card.

26. The main board as claimed in claim 25, wherein the dual unidirectional point-to-point bus socket is compatible as a HyperTransport (HT) socket.

27. The main board as claimed in claim 25, wherein the dual unidirectional point-to-point bus socket comprises a covering thereon, the covering comprising a Y-shaped opening for guiding the connection card inserted into the dual unidirectional point-to-point bus socket.

28. The main board as claimed in claim 26, wherein the slot comprises a plurality of pins therein defined as HyperTransport (HT) pins for providing electronically connection with the connection card.

29. A socket for providing connection between a connection card and a main board, wherein the socket is located on the main board, the socket comprising:
a slot for the connection card to be inserted into; and
a plurality of pins configured in the slot;
wherein the pins are defined as HyperTransport (HT) pins, and the socket has a physical structure compatible as a PCI-Express socket.

30. The socket as claimed in claim 29, further comprising a covering thereon, the covering comprising a Y-shaped opening for guiding the connection card inserted into the slot.

31. The socket as claimed in claim 29, wherein each pin is configured as a zigzag shape, and every two pins are configured in opposite such that the connection card can be pressed from both side thereof.
